(19) United States
(12) Patent Application Publication
(10) Pub. No.: US 2025/0269435 A1
(43) Pub. Date: Aug. 28, 2025

(54) COATED CUTTING TOOL

(71) Applicant: WALTER AG, Tubingen (DE)

(72) Inventors: Veit SCHIER, Tubingen (DE); Wolfgang ENGELHART, Tubingen (DE)

(21) Appl. No.: 18/857,896

(22) PCT Filed: Apr. 20, 2023
(86) PCT No.: PCT/EP2023/060313

§ 371 Date: Oct. 18, 2024

(30) Foreign Application Priority Data
Apr. 21, 2022 (EP) 22169222.1

(51) Int. Cl. B23B 27/14; C23C 30/00

(52) U.S. Cl. CPC B23B 27/148; C23C 30/005; B23B 2224/00; B23B 2228/08; B23B 2228/105; B23B 2228/36

(57) ABSTRACT

A coated cutting tool includes a substrate and a coating. The coating has a monolithic layer of (Ti,Al,Si)N with an average composition of Ti_{1-x-y}AlₓSi_{y}N, 0.50≤x≤0.60, 0.03≤y≤0.08 and a thickness from 0.5 to 15 μm. The layer of (Ti,Al,Si)N has a structure of columnar crystal grains. The layer of (Ti,Al,Si)N includes two different cubic phases, one cubic phase being present in the columnar crystal grains and one cubic phase being a grain boundary phase located between columnar crystal grains, wherein the layer of (Ti,Al,Si)N has a plane strain modulus of ≥425 GPa.

### TECHNICAL FIELD

The present invention relates to a coated cutting tool for metal machining wherein the cutting tool has a coating comprising a (Ti,Al,Si)N layer.

### BACKGROUND

There is a continuous desire to improve cutting tools for metal machining so that they last longer, withstand higher cutting speeds and/or other increasingly demanding cutting operations.

Generally, cutting tools for metal machining comprise a substrate of a hard material such as cemented carbide, cubic boron nitride, or cermet, and a wear resistant coating deposited on the surface of the substrate. The wear resistant coating is usually deposited by either chemical vapour deposition (CVD) or physical vapour deposition (PVD).

The coating should ideally have a high hardness but at the same time possess sufficient toughness in order to withstand severe cutting conditions as long as possible.

A coating for a metal cutting tool should also ideally have a low thermal conductivity since this correlates to the heat resistance of a coating.

There are different methods of PVD and they give different characteristics of the deposited coating.

Cathodic arc evaporation uses an electric arc to vaporise material from a cathode target. The vaporised material, or a compound thereof, is then condensed on a substrate. Cathodic arc evaporation has advantages of high deposition rate but drawbacks such as droplets of target material are included in the coating and as well on the surface. This may create weakness in the coating and a comparatively rough surface. In many metal cutting applications a smooth surface of a deposited wear resistant coating is beneficial.

Reactive sputtering is a second method of PVD. In this method a plasma of ionised inert gas is created which is made bombarding a target material. Atoms from the target material are ejected and accelerated towards a substrate in the presence of a reactive gas, e.g., nitrogen. Since there is no problem with droplet formation a coating with a smooth surface is generally obtained. However, there is quite difficult to get a high metal ionisation. Also, sputtering is a quite slow deposition process.

High-power impulse magnetron sputtering (HIPIMS) is a special type of sputtering allowing for great flexibility in varying process parameters, especially the power level used (average power, peak pulse power) in combination with pulse on-time and using high bias voltages. HIPIMS enables high metal ionisation and allows for high quality coatings to be provided and by controlling the levels of metal ionisation very special coatings may be produced.

In a severe cutting condition the thermal resistance of the coating is particularly important. By thermal resistance is herein meant a low thermal conductivity of the coating which then protects the cutting tool body from excessive heat which is damaging for the substrate. The more heat protective the coating is the better the wear resistance of the coated cutting tool. A better wear resistance means a longer tool life.

PVD (Ti,Al)N coatings are commonly used as wear resistant coatings in cutting tools.

Generally, a sufficiently high Al content is desired as the oxidation stability of a (Ti,Al)N coating is better with increased Al content. Also, the hot hardness increases by increasing the Al content. However, one still wants a cubic crystal structure in order to provide high hardness and high plane strain modulus.

It is known that the high temperature stability of a coating is improved by including Si within (Ti,Al)N providing a (Ti,Al,Si)N coating.

However, a drawback with (Ti,Al,Si)N is that already at moderate Al contents of the metal elements, together with Si in an amount of only a couple of at % of the metal elements, a further structure may form which is hexagonal or amorphous, such as an amorphous grain boundary phase. A hexagonal phase, as well as an amorphous phase, contributes to bad mechanical properties, such as insufficient hardness and insufficient plane strain modulus.

It is therefore desired to provide a (Ti,Al,Si)N coating with a comparatively high Al content in which the benefits of Si can be enjoyed, the (Ti,Al,Si)N coating having excellent mechanical properties and heat stability.

The object of the present invention is to provide a coated cutting tool comprising a layer of (Ti,Al,Si)N having improved tool life over prior art coated cutting tools.

### The Invention

It has now been provided a coated cutting tool comprising a substrate and a coating, wherein the coating comprises a from 0.5 to 15 μm monolithic layer of (Ti,Al,Si)N with an average composition Ti_{1-x-y}AlₓSi_{y}N, 0.50≤x≤0.60, 0.03≤y≤0.08, the layer of (Ti,Al,Si)N has a structure of columnar crystal grains, the layer of (Ti,Al,Si)N comprises two different cubic phases, one cubic phase being present in the columnar crystal grains and one cubic phase being a grain boundary phase located between columnar crystal grains, the layer of (Ti,Al,Si)N has a plane strain modulus of 425 GPa.

In the Ti_{1-x-y}AlₓSi_{y}N, suitably 0.52≤x≤0.58.

In the Ti_{1-x-y}AlₓSi_{y}N, suitably 0.03≤y≤0.07, preferably 0.04≤y≤0.06.

In a preferred embodiment, in the Ti_{1-x-y}AlₓSi_{y}N, 0.52≤x≤0.58 and 0.03≤y≤0.07.

In a most preferred embodiment, in the Ti_{1-x-y}AlₓSi_{y}N, 0.52≤x≤0.58 and 0.04≤y≤0.06.

The layer of (Ti,Al,Si)N of this disclosure is monolithic, i.e., substantially uniform in its properties and its elemental contents throughout the (Ti,Al,Si)N layer, in contrast to a multilayered (Ti,Al,Si)N layer.

If the aluminium content x in Ti_{1-x-y}AlₓSi_{y}N is less than 0.50 then there is insufficient oxidation stability and hot hardness giving less performance in metal cutting. If, on the other hand, the aluminium content x in Ti_{1-x-y}AlₓSi_{y}N is higher than 0.60 then there is a risk of introduction of hexagonal phase within the (Ti,Al,Si)N layer leading to worse mechanical properties such as lower hardness and lower plane strain modulus giving less performance in metal cutting.

If the silicon content y in Ti_{1-x-y}AlₓSi_{y}N is less than 0.03 then there is no, or insufficient amount of, grain boundary phase giving less performance in metal cutting. If, on the other hand, the silicon content y in Ti_{1-x-y}AlₓSi_{y}N is higher than 0.08 then there is a risk of introduction of hexagonal phase within the (Ti,Al,Si)N layer leading to worse mechanical properties such as lower hardness and lower plane strain modulus giving less performance in metal cutting.

The determination of crystal structure or structures present in the (Ti,Al,Si)N layer is suitably made by X-ray diffraction analysis, alternatively TEM analysis.

The FWHM (Full Width at Half Maximum) of a diffraction peak in X-ray diffraction analysis depends on both the degree of crystallinity in the (Ti,Al,Si)N layer and the grain size of crystallites. The smaller the FWHM value, the higher the crystallinity and/or the larger the grain size.

In one embodiment, the (Ti,Al,Si)N layer comprises a cubic crystal structure and wherein the FWHM (Full Width at Half Maximum) of the cubic (200) peak in a theta-2theta scan in X-ray diffraction using Cu k-alpha radiation is from 0.4 to 1.5 degrees 2theta, preferably from 0.5 to 1.0 degrees 2theta.

The degree of crystallinity in itself in the (Ti,Al,Si)N layer can be expressed as measured by a peak-to-background ratio in X-ray diffraction analysis. At low crystallinity the diffraction intensity of every (hkl) peak from a certain crystal structure in a theta-2theta scan is low and its relation to the background intensity is, thus, low. One can use the following expression: the intensity of the highest peak Iₘₐₓ in a theta-2theta scan of a certain crystal structure minus the intensity of the background at the 2theta position of the peak, I_{background}, divided by the intensity of the background at the 2theta position of the peak, I_{background}, i.e.,

$$Peak - to - background ratio = ( {I}_{max} - {I}_{background} ) / {I}_{background} .$$

The highest peak of a crystal structure is used as Iₘₐₓ in the formula since a crystal structure may be of different preferred crystallographic orientations and the relation between intensities of the different (hkl) peaks in a crystal structure may vary.

For the (Ti,Al,Si)N layer of the present invention, the cubic (200) peak is in one embodiment the one of the cubic peaks showing the highest intensity in an X-ray diffraction theta-2theta scan.

In one embodiment the (Ti,Al,Si)N layer has a peak-to-background ratio in X-ray diffraction analysis using Cu k-alpha radiation for the cubic (200) peak of ≥3, preferably ≥4. The peak-to-background ratio in X-ray diffraction analysis using Cu k-alpha radiation for the cubic (200) peak of the (Ti,Al,Si)N layer is in combination of any one of the lower limits suitably ≤15, preferably ≤12.

The columnar crystal grains in the layer of (Ti,Al,Si)N are suitably of single phase cubic crystal structure.

The grain boundary phase has an average composition Ti_{1-z-v}Al_{z}SiᵥN of suitably 0.40≤z≤0.55, preferably 0.43≤z≤0.52, and suitably 0.06≤v≤0.13, preferably 0.07≤v≤0.12.

In one embodiment, v>y.

In one embodiment v/y is >1 but ≤3.5, or v/y is 1.2 but 3, or v/y is 1.5 but 2.5.

In one embodiment x/z is ≥1 but ≤1.5, or x/z is ≥1.1 but ≤1.3.

In one embodiment the average thickness of the grain boundary phase between columnar crystal grains is from 0.5 to 10 nm, suitably from 1 to 5 nm.

In one embodiment, the (Ti,Al,Si)N layer comprises lattice planes crossing through the columnar crystal grains and the grain boundary phase.

In addition to the cubic phase being present in the columnar crystal grains and the cubic phase being a grain boundary phase there may be a small amount of another phase present in the layer of (Ti,Al,Si)N, such as a hexagonal phase or an amorphous phase. Such phases will give a small, broad, diffraction peak in theta-2theta X-ray diffraction covering the range of about 30 to 40 degrees 2theta. The peak-to-background ratio in X-ray diffraction analysis using Cu k-alpha radiation for this peak is suitably ≤0.25, preferably ≤0.2, most preferably ≤0.15.

In one embodiment, the (Ti,Al,Si)N layer has a thermal conductivity of ≤5 W/mK, preferably from 2 to 4 W/mK. For wear resistant coatings on cutting tools a low thermal conductivity is beneficial to keep the thermal load from the cutting process on the tool substrate as low as possible.

In one embodiment, the (Ti,Al,Si)N layer has a residual compressive stress of from 1.5 to 6 GPa, preferably from 2 to 4 GPa. If the residual compressive stress is too low then the toughness of the coating may be insufficient. If, on the other hand, the residual compressive stress is too high then flaking of the coating may occur.

In one embodiment, there is an innermost layer of the coating, directly on the substrate, of a nitride of one or more elements belonging to group 4, 5 or 6 of the periodic table of elements, or a nitride of Al together with one or more elements belonging to group 4, 5 or 6 of the periodic table of elements. This innermost layer acts as a bonding layer to the substrate increasing the adhesion of the overall coating to the substrate. Such a bonding layer are commonly used in the art and a skilled person would choose a suitable one. Preferred alternatives for this innermost layer are TiN or (Ti,Al)N. The thickness of this innermost layer may vary and depends, for example, on the type of cutting tool, i.e., a coated insert may have another optimal thickness of its innermost layer than a coated drill. The thickness of this innermost layer is suitably less than 2 μm. The thickness of this innermost layer is in one embodiment from 5 nm to 2 μm, preferably from 10 nm to 1 μm. Since there may also be a need to have an innermost layer functioning as a barrier for Co diffusion into the coating there is a need for the thickness to be at least 50 nm. Si-containing nitride layers are known to attract Co more than most other metal nitride layers. Thus, in a further embodiment this innermost layer is from 50 nm to 2 μm, preferably from 100 nm to 1 μm.

In one embodiment, the (Ti,Al,Si)N layer has a Vickers hardness of 3500 HV (15 mN load), preferably from 3500 to 3800 HV (15 mN load).

The (Ti,Al,Si)N layer has suitably a plane strain modulus of from 425 to 540 GPa, preferably from 450 to 530 GPa.

The thickness of the (Ti,Al,Si)N layer is suitably from 0.5 to 10 μm, preferably from 1 to 6 μm.

If the thickness of the (Ti,Al,Si)N layer is less than 0.5 μm then there is an insufficient effect of the (Ti,Al,Si)N layer in metal cutting. If, on the other hand, the thickness of the (Ti,Al,Si)N layer is more than 15 μm then there is a risk of flaking of the coating giving less performance in metal cutting.

The substrate of the coated cutting tool can be of any kind common in the field of cutting tools for metal machining. The substrate is suitably selected from cemented carbide, cermet, cubic boron nitride (cBN), ceramics, polycrystalline diamond (PCD) and high speed steel (HSS).

In one preferred embodiment, the substrate is cemented carbide.

The coated cutting tool has suitably at least one rake face and at least one flank face and a cutting edge inbetween.

The coated cutting tool is suitably in the form of an insert, a drill or an end mill.

The (Ti,Al,Si)N layer according to the invention is suitably a layer deposited by sputtering, preferably a High-Power Impulse Magnetron Sputtering (HIPIMS)—deposited layer.

### BRIEF DESCRIPTION OF THE DRAWINGS

FIG. 1 shows a schematic view of one embodiment of a cutting tool being a milling insert.

FIG. 2 shows a schematic view of a cross section of an embodiment of the coated cutting tool of the present invention showing a substrate and a coating.

FIG. 3 shows a dark-field TEM image of Sample 1 (invention) showing a grain boundary phase visualised as darker areas is seen between columnar crystal grains.

FIG. 4 shows a high-resolution TEM (HR-TEM) dark-field image where one sees lattice planes crossing through the columnar crystal grains as well as the darker grain boundary phase.

FIG. 5 shows X-ray diffractograms from theta-2theta scans for the (Ti,Al,Si)N layer of Sample 1 (invention) as deposited and after heat treatment at 950° C.

FIG. 6 shows X-ray diffractograms from theta-2theta scans for the (Ti,Al,Si)N layer of Sample 2 (invention) as deposited and after heat treatment at 950° C.

FIG. 7 shows X-ray diffractograms from theta-2theta scans for the (Ti,Al,Si)N layer of Sample 3 (comparative) as deposited and after heat treatment at 950° C.

FIG. 8 shows an X-ray diffractogram from a theta-2theta scan for the (Ti,Al,Si)N layer of Sample 4 (comparative) as deposited.

### DETAILED DESCRIPTION OF EMBODIMENTS IN DRAWINGS

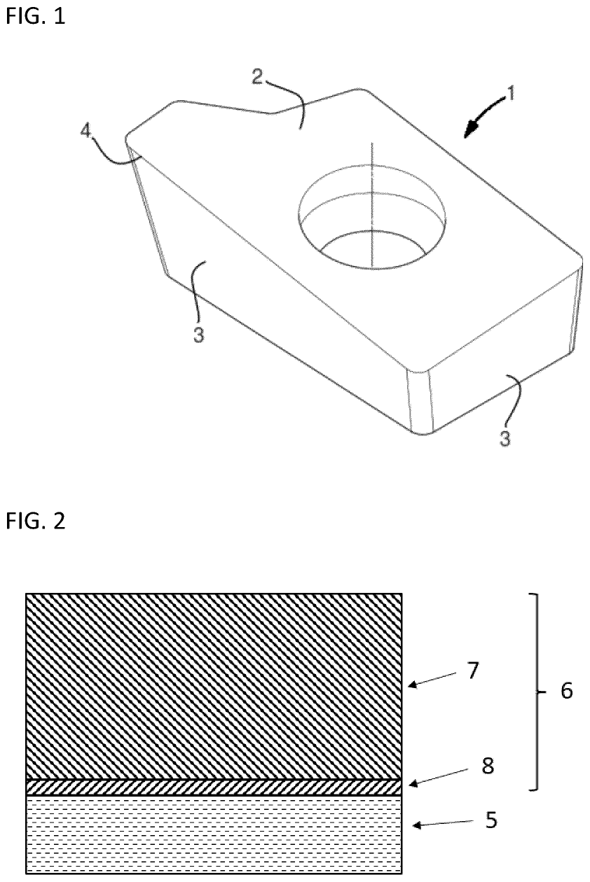

FIG. 1 shows a schematic view of one embodiment of a cutting tool (1) having a rake face (2), a flank face (3) and a cutting edge (4). The cutting tool (1) is in this embodiment a milling insert. FIG. 2 shows a schematic view of a cross section of an embodiment of the coated cutting tool of the present invention having a substrate body (5) and a coating (6). The coating (6) consisting of a first thin (Ti,Al)N innermost layer (8) followed by a (Ti,Al,Si)N layer (7).

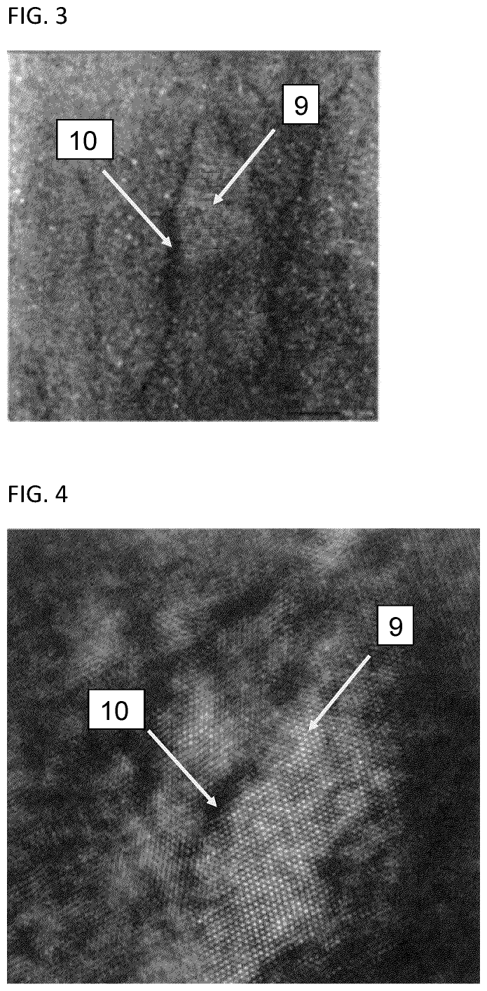

FIG. 3 shows a dark-field TEM image of Sample 1 (invention). A structure is seen where bright (9) and dark (10) areas indicate different elemental compositions. The bright areas (9) being columnar crystal grains and the dark areas (10) being a grain boundary phase.

FIG. 4 shows a high resolution transmission electron microscope (HR-TEM) image of an cross-section of an embodiment of the (Ti,Al,Si)N layer. The bright areas (9) being columnar crystal grains and the dark areas (10) being a grain boundary phase. It is seen a pattern of stripes from the crystal structure over the whole (Ti,Al,Si)N layer analysed, Thus, lattice planes are crossing through the columnar crystal grains (9) and grain boundary phase (10).

### Methods

### X-Ray Diffraction:

The X-ray diffraction patterns were acquired by Grazing incidence mode (GIXRD) on a diffractometer from Panalytical (Empyrean). Cu—Kα-radiation with line focus was used for the analysis (high tension 40 kV, current 40 mA). The incident beam was defined by a 2 mm mask and a ⅛° divergence slit in addition with a X-ray mirror producing a parallel X-ray beam. The sideways divergence was controlled by a Soller slit (0.04°). For the diffracted beam path a 0.18° parallel plate collimator in conjunction with a proportional counter (OD-detector) was used. The measurement was done in grazing incidence mode (Omega=1°). The 2theta range was about 20-80° with a step size of 0.03° and a counting time of 10 s. The peak analysis was made using software HighScore from PANalytical B.V.

### Tem-Analysis:

The Transmission Electron Microscopy data (selected area diffraction patterns and dark field images) was acquired by a Transmission Electron Microscope Joel ARM200F. For the analysis, a high tension of 300 kV was used.

When reference is made herein to electron diffraction experiments these are TEM measurements which were carried out with parallel illumination. The area of interest was selected with a selected area aperture.

For TEM sample preparation a FIB (Focused Ion Beam) Lift out was used. For the final polishing the Ga-Ion beam was adjusted to a low current of about 200-500 pA at a low voltage of about 5 kV.

A cross-section of the coating was analysed perpendicular to surface of the coating.

Analysis of thickness of the grain boundary phase can be made by image analysis by determining the variation in brightness of the TEM image along an intersecting line. Since the grain boundary phase is dark in the image the thickness can be determined. A sufficient length of and/or number of intersecting lines is/are drawn so to provide a reliable average value of the grain boundary phase thickness. Suitably, at least 20 grain boundaries are intersected and an average value is calculated.

### Elemental Content:

The content of metal elements, nitrogen and argon in the coating can be measured by using Scanning Transmission Electron Microscopy (STEM) with Energy Dispersive X-Ray Spectroscopy (EDX) on a cross sectional FIB-prepared sample. For TEM imaging and EDX analysis used in the analysis within this disclosure, Jeol ARM System instrument was used, equipped with a field emission gun, secondary electron-dectector and Si(Li) energy dispersive x-ray (EDX) detector from Oxford Instruments. Either using a spot size small enough for probing, e.g., a grain boundary or use STEM mode to get an elemental mapping over a distance in the coating.

### Residual Stress

The residual stresses were measured by XRD using the sin²ψ method (c.f. M. E. Fitzpatrick, A. T. Fry, P. Holdway, F. A. Kandil, J. Shackleton and L. Suominen—A Measurement Good Practice Guide No. 52; “Determination of Residual Stresses by X-ray Diffraction—Issue 2”, 2005).

The side-inclination method (P-geometry) has been used with eight ψ-angles, equidistant within a selected sin²ψ range. An equidistant distribution of ϕ-angles within a ϕ-sector of 90° is preferred. For the calculations of the residual stress values, the Poisson's ratio=0.20 and the Young's modulus E=450 GPa have been applied. For measurements on the (Ti,Al,Si)N layer the data were evaluated using commercially available software (RayfleX Version 2.503) locating the (2 0 0) reflection of (Ti,Al,Si)N by the Pseudo-Voigt-Fit function. For measurements of residual stress of a layer of a coating having further deposited layers above itself coating material is removed above the layer to be measured. Care has to be taken to select and apply a method for the removal of material which does not significantly alter the residual stress within the remaining (Ti,Al,Si)N multilayer material. A suitable method for the removal of deposited coating material may be polishing, however, gentle and slow polishing using a fine-grained polishing agent should be applied. Strong polishing using a coarse grained polishing agent will rather increase the compressive residual stress, as it is known in the art. Other suitable methods for the removal of deposited coating material are ion etching and laser ablation.

### Thermal Conductivity

The thermal conductivity of a coating made herein used the Time-domain thermoreflectance (TDTR) method which has the following characteristics:
1. A laser pulse (Pump) is used to heat the sample locally.
2. Depending on the thermal conductivity and heat capacity, the heat energy is transferred from the sample surface towards the substrate. The temperature on the surface decreases by time.
3. The part of the laser being reflected depends on the surface temperature. A second laser pulse (probe pulse) is used for measuring the temperature decrease on the surface.
4. By using a mathematical model the thermal conductivity can be calculated also using the heat capacity value of the sample. Reference is made to (D. G. Cahill, Rev. Sci. Instr. 75,5119 (2004)).

The samples should be polished into mirror-like finish before the measurement.

### Vickers Hardness:

The Vickers hardness was measured by means of nano indentation (load-depth graph) using a Picodentor HM500 of Helmut Fischer GmbH, Sindelfingen, Germany. For the measurement and calculation the Oliver and Pharr evaluation algorithm was applied, wherein a diamond test body according to Vickers was pressed into the layer and the force-path curve was recorded during the measurement. The maximum load used was 15 mN (HV 0.0015), the time period for load increase and load decrease was 20 seconds each and the holding time (creep time) was 10 seconds. From this curve hardness was calculated.

### Plane Strain Modulus:

The elastic properties of the coating samples were characterized by the so-called plane strain modulus Eₚₛ as derived by nanoindentation via the Oliver and Pharr method. The nano-indentation data was obtained from indentation as described for Vickers hardness above.

### Thickness:

The thickness of the coating layers was determined by calotte grinding. Thereby a steel ball was used having a diameter of 30 mm for grinding the dome shaped recess and further the ring diameters were measured, and the layer thicknesses were calculated therefrom. Measurements of the layer thickness on the rake face (RF) of the cutting tool were carried out at a distance of 2000 μm from the corner, and measurements on the flank face (FF) were carried out in the middle of the flank face of a polished test sample.

### EXAMPLES

### Example 1 (Invention)

A start layer of (Ti,Al)N was deposited onto WC—Co based substrates using three targets with the composition Ti_{0.40}Al_{0.60}. Then, a (Ti,Al,Si)N layer was further deposited using three targets with the composition Ti_{0.40}Al_{0.55}Si_{0.06}. The WC—Co based substrates were cutting tools being milling inserts of geometry ADMT 160608R-F56, ROHX1204M0-D67, and as well flat inserts (for easier analysis of the coating) using HIPIMS mode in an Oerlikon Balzers Ingenia equipment using S3p technology. The substrates had a composition of 8 wt % Co and balance WC.

The uncoated insert blanks were mounted and rotated in the PVD chamber during deposition of the coating.

The deposition process was run in HIPIMS mode using the following process parameters

Start layer of (Ti,Al)N:
Target material: Ti_{0.40}Al_{0.60} (three targets)
Target size: circular, diameter 160 mm
Thickness: 12 mm
Average power per target: 9.06 kW
Peak pulse power: 60 kW
Pulse on time: 7.56 ms
Temperature: 430° C.
Total pressure: 0.6 Pa (N2+Ar)
Argon pressure: 0.42 Pa
Bias potential: −40 V
Number of repeating pulses
per cycle: 1

A layer thickness of about 200 nm was deposited.

### Layer of (Ti,Al,Si)N:

Target material: Ti_{0.40}Al_{0.54}Si_{0.06}
Target size: circular, diameter 160 mm
Thickness: 12 mm
Average power per target: 4.8 kW
Peak pulse power: 60 kW
Pulse on time: 4 ms
Temperature: 430° C.
Total pressure: 0.6 Pa
Argon pressure: 0.42 Pa
Bias potential: −40 V
Number of repeating pulses
per cycle: 1

A (Ti,Al,Si)N layer with a thickness of about 2.5 μm was deposited on the milling inserts, as measured on the flank face of an insert.

The coated cutting tool provided is called “Sample 1 (invention)”.

### Example 2 (Invention)

A further sample within the invention was made in the same way as described in Example 1 with the exception that the target material used in the process for depositing the (Ti,Al,Si)N layer was Ti_{0.40}Al_{0.56}Si_{0.04} instead of Ti_{0.40}Al_{0.54}Si_{0.06}.

The WC—Co based substrates were cutting tools being flat inserts (for easier analysis of the coating).

A (Ti,Al,Si)N layer with a thickness of about 1.5 μm was deposited on the inserts, as measured on the rake face of an insert.

The coated cutting tool provided is called “Sample 2 (invention)”.

### Example 3 (Comparative)

A further sample within the invention was made in the same way as described in Example 1 with the exception that the target material used in the process for depositing the (Ti,Al,Si)N layer was Ti_{0.39}Al_{0.59}Si_{0.02} instead of Ti_{0.40}Al_{0.54}Si_{0.06}.

The WC—Co based substrates were cutting tools being flat inserts (for easier analysis of the coating).

A (Ti,Al,Si)N layer with a thickness of about 1.6 μm was deposited on the inserts, as measured on the rake face of an insert.

The coated cutting tool provided is called “Sample 3 (comparative)”.

### Example 4 (Comparative)

A (Ti,Al,Si)N layer from a target with the composition Ti_{0.35}Al_{0.55}Si_{0.10} was deposited onto WC—Co based substrates of a milling insert type ADMT 160608R-F56 as well as flat cutting inserts (for easy analysis of the coating). The substrates had a composition of 8 wt % Co and balance WC. The uncoated insert blanks were mounted and rotated in the PVD chamber during deposition of the coating.

The deposition was made using HIPIMS mode in an Oerlikon Balzers equipment using S3p technology using the following process parameters:
Target material 2: Ti_{0.35}Al_{0.55}Si_{0.10}
Target size: circular, diameter 150 mm
Average power per target: 5.1 kW
Peak pulse power: 30 kW
Pulse on time: 0.2 ms
Pulse frequency 20 Hz
Temperature: 450° C.
Total pressure: 0.64 Pa
Argon pressure: 0.43 Pa
Bias potential: −80 V
Number of repeating pulses
per cycle: 43

A (Ti,Al,Si)N layer with a thickness of about 2.5 μm was deposited on the milling inserts, as measured on the flank face of an insert.

The coated cutting tool provided is called “Sample 4 (comparative)”.

### Example 5 (Comparative)

A (Ti,Al,Si)N layer from a target with the composition Ti_{0.40}Al_{0.54}Si_{0.06} was deposited onto WC—Co based substrates of a milling insert with SPMW12 geometry as well as flat cutting inserts (for easy analysis of the coating). The substrates had a composition of 8 wt % Co and balance WC. The uncoated insert blanks were mounted and rotated in the PVD chamber during deposition of the coating.

The deposition was made using cathodic arc deposition in an Hauzer HTC1000 equipment using the following process parameters:

### Start Layer of (Ti,Al)N:

Target material: Ti_{0.40}Al_{0.60}
Target size: circular, diameter 104 mm
Arc current: 150 A
Pressure N₂: 10 Pa
Temperature: 430° C.
Bias potential: −40 V

A layer thickness of about 340 nm was deposited.

(Ti,Al,Si)N layer:
Target material: Ti_{0.40}Al_{0.54}Si_{0.06}
Target size: circular, diameter 104 mm
Arc current: 150 A
Pressure N₂: 10 Pa
Temperature: 430° C.
Bias potential: −60 V

A (Ti,Al,Si)N layer with a thickness of about 2.5 μm was deposited on the milling inserts, as measured on the flank face of an insert.

The coated cutting tool provided is called “Sample 5 (comparative)”.

### Example 6 (Comparative)

A (Ti,Al)N layer from a target with the composition Ti_{0.40}Al_{0.60} was deposited onto WC—Co based substrates being cutting tools of a milling insert type ROHX1204M0-D67 and as well flat inserts (for easier analysis of the coating) using HIPIMS mode in an Oerlikon Balzers equipment using S3p technology. This HIPIMS-deposited coating was known to give very good results in machining of stainless steel (ISO-M) materials.

The substrates had a composition of 8 wt % Co and balance WC. The uncoated insert blanks were mounted and rotated in the PVD chamber during deposition of the coating.

The deposition process was run in HIPIMS mode using the following process parameters
Target material 1: Ti_{0.40}Al_{0.60}
Target size: circular, diameter 160 mm
Target thickness: 12 mm
Average power per target: 4.8 kW
Peak pulse power: 60 kW
Pulse on time: 4 ms
Temperature: 430° C.
Total pressure: 0.55 Pa
Argon pressure: 0.43 Pa
Bias potential: −80 V
Number of repeating pulses
per cycle: 1

A (Ti,Al,Si)N layer with a thickness of about 2.5 μm was deposited on the milling inserts, as measured on the flank face of an insert.

The coated cutting tool provided is called “Sample 6 (comparative)”.

### Example 7 (Analysis)

X-ray diffraction (XRD) theta-2theta analysis was made on Samples 1-4.

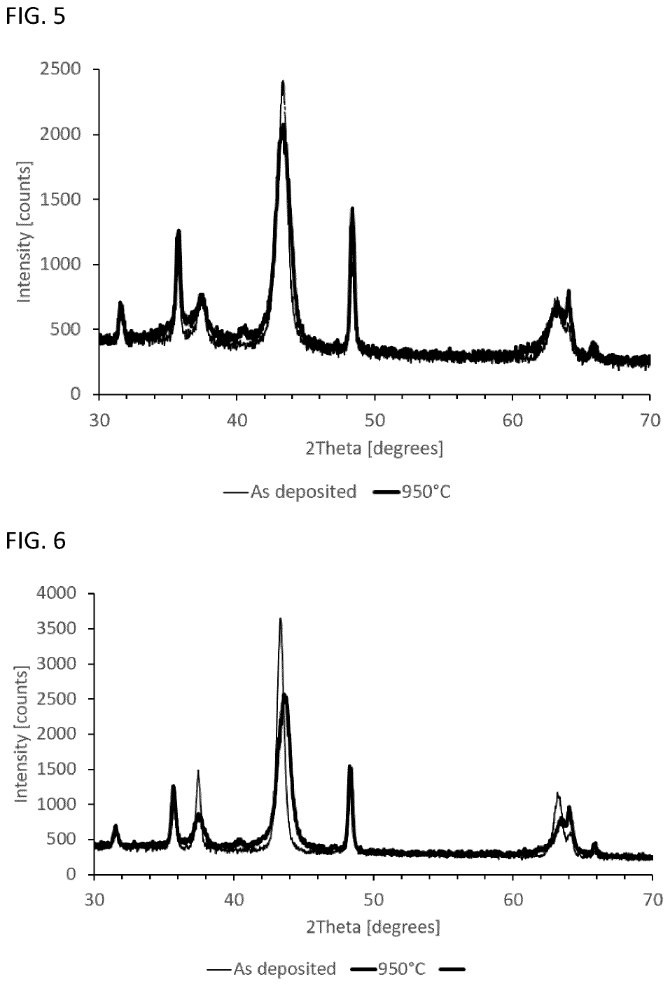

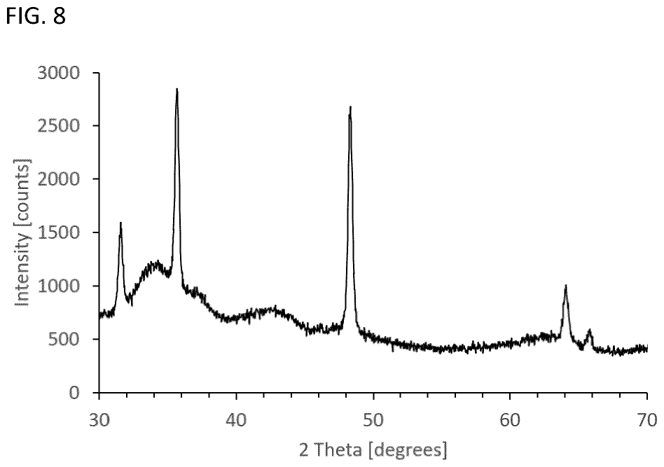

FIGS. 5-8 show the XRD theta-2theta diffractograms for Sample 1 (invention), Sample 2 (invention), Sample 3 (comparative) and Sample 4 (comparative).

It is seen that the diffractograms for Sample 1 (invention) and Sample 2 (invention) reveal a cubic crystal structure. The diffractograms show significant cubic (111) and cubic (200) peaks at around 37-38 degrees 2theta and around 43-44 degrees 2theta, respectively. The peaks are also quite sharp which implies significant crystallinity. The peak with the highest intensity is the (200) peak. The peak-to-background ratio for the (200) peak is estimated to be about 5.0 for Sample 1 (invention) and about 8.1 for Sample 2 (invention).

The FWHM (Full Width at Half Maximum) of the cubic (200) peak is about 0.8 degrees 2theta for Sample 1 (invention) and about 0.6 degrees 2theta for Sample 2 (invention).

The diffractogram for Sample 4 (comparative) shows much less significant cubic (111) and cubic (200) peaks than Sample 1 (invention) and Sample 2 (invention). The (111) peak can hardly be distinguished from a broad underlying reflection which ranges from about 31-39 degrees 2theta. There is also a broad underlying reflection ranging from about 40-45 degrees 2theta which covers the position where the cubic (200) peak is. These broad reflections implies presence of significant amorphous structure. The much lower degree of crystallinity can be determined from the peak-to-background ratio for the (200) peak which is only estimated to be about 0.3.

The Full Width at Half Maximum (FWHM) of this less significant cubic (200) peak is quite difficult to determine but is estimated to be about 4 degrees 2theta.

The average content of each metal element in the (Ti,Al,Si)N layer is considered to reflect the target composition, i.e., the layers deposited are regarded as seen in Table 1.

TABLE 1

| | Average composition |
|---|---|
| Sample 1 (invention) | Ti_{0.40}Al_{0.54}Si_{0.06}N |
| Sample 2 (invention) | Ti_{0.40}Al_{0.56}Si_{0.04}N |
| Sample 3 (comparative) | Ti_{0.39}Al_{0.59}Si_{0.02}N |
| Sample 4 (comparative) | Ti_{0.35}Al_{0.55}Si_{0.10}N |
| Sample 5 (comparative, arc- | Ti_{0.40}Al_{0.54}Si_{0.06}N |
| deposited) | |
| Sample 6 (comparative) | Ti_{0.40}Al_{0.60}N |

Transmission electron Microscopy (TEM) analysis was made on Sample 1 (invention), Sample 2 (invention) and Sample 3 (comparative). A columnar microstructure was seen in their (Ti,Al,Si)N layers. Further observing dark-field imaging of the (Ti,Al,Si)N layer of the samples revealed the presence of a grain boundary phase for Sample 1 (invention) and Sample 2 (invention). No grain boundary phase could be seen in a dark-field TEM image of Sample 3 (comparative). Also, no grain boundary phase could be seen in a dark-field TEM image of the (Ti,Al,Si)N layer of Sample 5 (comparative). FIG. 3 shows a dark-field TEM image of the (Ti,Al,Si)N layer of Sample 1 (invention). It is seen that the a grain boundary phase visualised as darker areas is seen between columnar crystal grains.

Furthermore, from a high-resolution TEM (HR-TEM) dark-field image of the (Ti,Al,Si)N layer of Sample 1 (invention), see FIG. 4, one sees lattice planes crossing through the columnar crystal grains as well as the darker grain boundary phase.

Through Electron Energy Loss Spectroscopy (EELS) of the (Ti,Al,Si)N layer of Sample 1 (invention) it was concluded that the grain boundary phase is a cubic (Ti,Al,Si)N phase. There is no ionisation edge in the EELS spectrum indicating any presence of a hexagonal phase. EELS spectra further indicates that the elemental contents of Ti, Al and Si in the grain boundary phase are different from the average elemental contents in the whole (Ti,Al,Si)N layer. In the EELS analysis Equipment Jeol ARM200F with an Gatan Quantum ER spectrometer was used. The high voltage was set to 300 kV. The system was more tuned for intensity instead of resolution meaning the energy resolution was only 1.3 eV. The spectra was acquired in STEM mode using Spot5, which is a measure for the spot size.

By using STEM-EDX, and measuring at 4 different positions in the grain boundary phase, the average elemental content of Ti, Al and Si in the grain boundary phase of Sample 1 (invention) was Ti: 43 at %, Al: 46 at % and Si: 11 at %.

For Sample 1 (invention) the thickness of the grain boundary phase was estimated from TEM analysis to be about 2 nm.

Furthermore, Scanning Electron Microscopy (SEM) analysis of Sample 5 (comparative) showed a columnar microstructure of the (Ti,Al,Si)N layer.

Residual stress was also measured on Sample 1 (invention) and Sample 2 (invention) showing values of between −2 to −3 GPa for as-deposited samples. Heat treatments were further made at 950° C. for a period of one hour and there was no significant relaxation, i.e., reduction of residual stress, seen which indicates no substantial formation of hexagonal phase.

TABLE 2

| | | Residual stress [GPa] | |
|---|---|---|---|
| | Average | | Heat treated |
| | composition | As deposited | 950° C. |
| Sample 1 | Ti_{0.40}Al_{0.54}Si_{0.06}N | −2.1 | −3.6 |
| (invention) | | | |
| Sample 2 | Ti_{0.40}Al_{0.54}Si_{0.04}N | −2.5 | −2.2 |
| (invention) | | | |

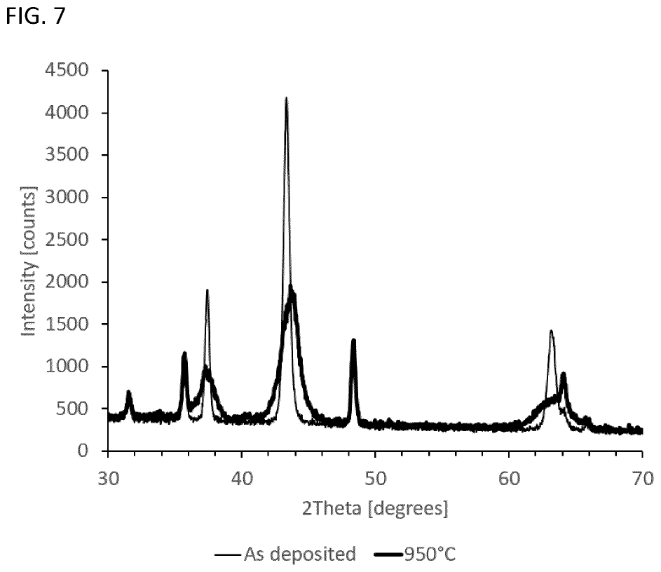

The phase stability was, furthermore, determined through XRD measurements for samples having been heat treated at 950° C. for one hour. When looking at, for example, the cubic (200) peak at about 42-43 degrees 2theta Sample 1 (invention) and Sample 2 (invention) showed only small changes in the (200) peak shape. See FIG. 5 and FIG. 6. However, Sample 3 (comparative) showed a significant broadening of the (200) peak, see FIG. 7, which indicates reduced crystallinity and/or other changes in the structure. Thus, Sample 3 (comparative) is less heat stable than Sample 1 (invention) and Sample 2 (invention).

The thermal conductivity was determined using the Time-domain thermoreflectance (TDTR) method. Table 3 shows the results.

TABLE 3

| | Average | | Thermal conductivity |
|---|---|---|---|
| | composition | Structure | [W/mK] |
| Sample 1 | Ti_{0.40}Al_{0.54}Si_{0.06}N | monolayer | 3.1 |
| (invention) | | | |
| Sample 6 | Ti_{0.40}Al_{0.60}N | monolayer | 5.4 |
| (comparative) | | | |

The result for Sample 1 (invention) was 3.1 W/mK, i.e., a low thermal conductivity, despite the cubic columnar structure, giving an advantage in heat generating severe metal cutting.

Hardness measurements (load 15 mN) were carried out on the coated tool of Samples 1-5 to determine Vickers hardness and plane strain modulus. Table 4 shows the results.

TABLE 4

| | | | Plane strain |
|---|---|---|---|
| | Average | Hardness HV | modulus, |
| | composition | [Vickers] | [GPa] |
| Sample 1 | Ti_{0.40}Al_{0.54}Si_{0.06}N | 3907 | 478 |
| (invention) | | | |
| Sample 2 | Ti_{0.40}Al_{0.54}Si_{0.04}N | 3754 | 527 |
| (invention) | | | |
| Sample 3 | Ti_{0.40}Al_{0.54}Si_{0.02}N | 3907 | 478 |
| (comparative) | | | |
| Sample 4 | Ti_{0.35}Al_{0.55}Si_{0.10}N | 2105 | 239 |
| (comparative) | | | |
| Sample 5 | Ti_{0.40}Al_{0.54}Si_{0.06}N | 2798 | 348 |
| (comparative) | (ARC-deposited) | | |

The very high values for plane strain modulus of well above 400 GPa reflect a high degree of cubic structure also for the samples according to the invention with 4 and 6 at % Si out of Ti, Al and Si. It was surprising that Sample 1 and Sample 2 had such high values for plane strain modulus.

### Example 8

### Cutting Test of Sample 1 (Invention) and Sample 4 (Reference):

Sample 1 (invention) and Sample 4 (comparative), being milling inserts of type ADMT160608R-F56, were tested in a milling test, and the average flank wear was measured. The cutting conditions are summarized in Table 5. As workpiece material stainless steel ISO-M was used.

### Cutting Conditions:

TABLE 5

| Workpiece Material | ISO-M; 1.4571/V4A |
|---|---|
| Tensile strength, Rm [N/mm²] | 470 |
| Cutter diameter, Dc [mm] | 63 |
| Number of teeth, Z | 3 |
| Cutting width, aₑ [mm] | 50 |
| Cutting depth, aₚ [mm] | 3 |
| Cutting speed V_{c} [m/min] | 240 |
| Tool length, Xₑ [mm] | 90 |

Three cutting edges were tested of each sample and the averaged value for each cutting length is shown in Table 6.

TABLE 6

| Sample 1 | Average | Cutting length | Average wear |
|---|---|---|---|
| (invention) | composition | [mm] | [mm] |
| Sample 1 | Ti_{0.40}Al_{0.54}Si_{0.06}N | 6400 | 0.15 |
| (invention) | | | |
| Sample 4 | Ti_{0.35}Al_{0.55}Si_{0.10}N | 5900 | 0.19 |
| (comparative) | | | |

Sample 1 (invention) performs better than Sample 4 (comparative).

### Cutting Test of Sample 1 (Invention) and Sample 6 (Reference):

Sample 1 (invention) and Sample 6 (comparative), being milling inserts of type ROHX1204M0-D67, were tested in a milling test, and the average flank wear was measured. The cutting conditions are summarized in Table 7. As workpiece material stainless steel ISO-M was used.

### Cutting Conditions:

TABLE 7

| Workpiece Material | ISO-M; 1.4301 |
|---|---|
| Tensile strength, Rm [HB] | 150-170 HB |
| Cutter diameter, Dc | 40 |
| Number of teeth, Z | 4 |
| Cutting width, aₑ [mm] | 23 |
| Cutting depth, aₚ [mm] | 1.5 |
| Cutting speed, V_{c} [m/min] | 255 |

Four cutting edges were tested of each sample and the averaged value for each cutting length is shown in Table 8.

TABLE 8

| Sample 1 | Average | Cutting length | Average wear |
|---|---|---|---|
| (invention) | composition | [mm] | [mm] |
| Sample 1 | Ti_{0.40}Al_{0.54}Si_{0.06}N | 4000 | 0.18 |
| (invention) | | 5600 | 0.39 |
| Sample 6 | Ti_{0.40}Al_{0.60}N | 4000 | 0.54 (stopped) |
| (comparative) | | 5600 | — |

Sample 1 (invention) performs better than Sample 6 (comparative).

### Cutting Test of Sample 1 (Invention) and Sample 5 (Comparative):

Sample 1 (invention) and Sample 5 (comparative), being milling inserts of type SPMW12, were tested in a milling test, and the flank wear was measured. The cutting conditions are summarized in Table 9. As workpiece material steel ISO-P, 42CrMo4, was used.

### Cutting Conditions:

TABLE 9

| Workpiece Material | ISO-P; 42CrMo4 |
|---|---|
| Tensile strength, Rm [N/mm²] | 800 |
| Cutter diameter, Dc | 125 |
| Number of teeth, Z | 1 |
| Cutting width aₑ [mm] | 100 |
| Cutting depth aₚ [mm] | 3 |
| Cutting speed V_{c} [m/min] | 280 |
| Tool length, Xₑ [mm] | 126 |

The wear value (as averaged over the cutting edge) for each cutting length is shown in Table 10.

TABLE 10

| Sample 1 | Average | Cutting length | Wear |
|---|---|---|---|
| (invention) | composition | [mm] | [mm] |
| Sample 1 | Ti_{0.40}Al_{0.54}Si_{0.06}N | 4800 | 0.20 |
| (invention) | | 5600 | 0.27 |
| Sample 5 | Ti_{0.35}Al_{0.55}Si_{0.06}N | 4800 | 0.36 |
| (comparative) | (ARC-deposited, no | 5600 | — |
| | grain boundary | | |
| | phase) | | |

Sample 1 (invention) performs better than Sample 5 (comparative).

1. A coated cutting tool comprising:
a substrate; and
a coating, wherein the coating comprises a monolithic layer of (Ti,Al,Si)N with an average composition Ti_{1-x-y}AlₓSi_{y}N, 0.50≤x≤0.60, 0.03≤y≤0.08 and having a thickness from 0.5 to 15 μm, the layer of (Ti,Al,Si)N having columnar crystal grains, wherein the layer of (Ti,Al,Si)N includes two different cubic phases, one cubic phase being present in the columnar crystal grains and one cubic phase being a grain boundary phase located between the columnar crystal grains, and wherein the layer of (Ti,Al,Si)N has a plane strain modulus of ≥425 GPa.

2. The coated cutting tool according to claim 1, wherein in the Ti_{1-x-y}AlₓSi_{y}N, 0.52≤x≤0.58 and 0.03≤y≤0.07.

3. The coated cutting tool according to claim 1, wherein the grain boundary phase has an average composition Ti_{1-z-v}Al_{z}SiᵥN, 0.40≤z≤0.55 and 0.06≤v≤0.13.

4. The coated cutting tool according to claim 3, wherein v>y.

5. The coated cutting tool according to claim 1, wherein an average thickness of the grain boundary phase between the columnar crystal grains is from 0.5 to 10 nm.

6. The coated cutting tool according to claim 1, wherein the (Ti,Al,Si)N layer includes lattice planes crossing through the columnar crystal grains and the grain boundary phase.

7. The coated cutting tool according to claim 1, wherein the (Ti,Al,Si)N layer has a thermal conductivity of ≤5 W/mK.

8. The coated cutting tool according to claim 1, wherein the (Ti,Al,Si)N layer has a residual compressive stress of from 1.5 to 6 GPa

9. The coated cutting tool according to claim 1, further comprising an innermost layer of the coating disposed directly on the substrate, the innermost layer being of a nitride of one or more elements belonging to group 4, 5 or 6 of the periodic table of elements, or a nitride of Al together with one or more elements belonging to group 4, 5 or 6 of the periodic table of elements, wherein a thickness of the innermost layer is from 5 nm to 2 μm.

10. The coated cutting tool according to claim 1, wherein the (Ti,Al,Si)N layer has a Vickers hardness of ≥3500 HV (15 mN load).

11. The coated cutting tool according to claim 1, wherein the (Ti,Al,Si)N layer has a plane strain modulus of from 425 to 540 GPa.

12. The coated cutting tool according to claim 1, wherein the thickness of the (Ti,Al,Si)N layer is from 0.5 to 10 μm.

13. The coated cutting tool according to claim 1, wherein the substrate is selected from cemented carbide, cermet, cubic boron nitride (cBN), ceramics, polycrystalline diamond and high speed steel.

14. The coated cutting tool according to claim 1, which is in the in the form of an insert, a drill or an end mill.
